(19) United States
(12) Patent Application Publication
(10) Pub. No.: US 2014/0357051 A1
(43) Pub. Date: Dec. 4, 2014

(54) METHOD FOR FORMING RADIO FREQUENCY DEVICE

(71) Applicant: Shanghai Huahong Grace Semiconductor Manufacturing Corporation, Shanghai (CN)

(72) Inventor: Ernest Li, Shanghai (CN)

(73) Assignee: Shanghai Huahong Grace Semiconductor Manufacturing Corporation, Shanghai (CN)

(21) Appl. No.: 14/156,865

(22) Filed: Jan. 16, 2014

(30) Foreign Application Priority Data
May 28, 2013 (CN) 201310205814.4

(51) Int. Cl. H01L 21/762

(52) U.S. Cl. CPC H01L 21/76275
USPC 438/458

(57) ABSTRACT

A method for forming a radio frequency device is provided. The method may include: providing a semiconductor-on-insulator layer, which comprises a back substrate, a buried oxide layer and a top semiconductor layer, where a plurality of transistors and an interlayer dielectric layer covering the plurality of transistors are formed on a surface of the top semiconductor layer; providing a temporary supporting layer having a smooth surface, and adhering a surface of the interlayer dielectric layer to the temporary supporting layer; removing the back substrate to expose the buried oxide; providing a high resistivity substrate, and adhering the high resistivity substrate to the buried oxide layer; and removing the temporary supporting layer to expose the surface of the interlayer dielectric layer after the high resistivity substrate and the buried oxide layer is adhered. Signal loss of the radio frequency devices may be reduced, and signal linearity is improved.

### CROSS-REFERENCE TO RELATED APPLICATIONS

The present application claims priority to Chinese patent application No. 201310205814.4, filed on May 28, 2013, and entitled “METHOD FOR FORMING RADIO FREQUENCY DEVICE”, the entire disclosure of which is incorporated herein by reference.

### TECHNICAL FIELD

The present disclosure generally relates to semiconductor manufacture technology, and more particularly, to a method for forming a Radio Frequency (RF) device.

### BACKGROUND

Semiconductor devices are developing to have high integration, high operation speed and low power consumption, which limit applications of bulk silicon substrate. On the contrary, Silicon-on-insulator (SOI) substrate has advantages of dielectric isolation of devices in integrated circuit, complete elimination of parasitic latch-up effect in COMS circuit on bulk silicon substrate, low parasitic capacitance, high integration density, high speed, simple process, small short-channel effect, and applicability for low-power and low-voltage circuits. Therefore, SOI substrate is increasingly popular in semiconductor device manufacture.

Radio Frequency (RF) devices require a small parasitic capacitance. A parasitic capacitance between devices and the substrate often plays a significant role. The parasitic capacitance can be effectively reduced by adopting a SOI substrate. In addition, high frequency characteristics of RF devices may be improved when the RF devices are fabricated on the SOI substrate.

A structural diagram of a SOI RF device in the prior art is schematically illustrated in FIG. 1. Referring to FIG. 1, a SOI substrate 1 includes a high resistivity silicon base 2, a Buried Oxide (BOX) layer 3 on the high resistivity silicon base 2, and a top silicon layer 4 on the BOX layer 3. A shallow trench isolation structure 5 is formed in the top silicon layer 4, so as to isolate active areas (not shown) in the top silicon layer 4. Semiconductor devices, such as transistors, are formed in the active areas of the top silicon layer 4. Metal interconnection structures are formed on the SOI substrate 1. As shown in FIG. 1, taking one layer Metal interconnection structure as an example, the one layer Metal interconnection structure includes: a interlayer dielectric layer 6 on the top silicon layer 4 and the shallow trench isolation structure 5, conductive plugs (not shown) formed in the interlayer dielectric layer 6, and a metal layer 7 on the interlayer dielectric layer 6 and the conductive plugs, where at least a part of the above of the shallow trench isolation structure 5 is covered by the metal layer 7.

However, it is found in actual application that, the SOI RF device has disadvantages of great signal loss and poor RF signal linearity in some RF applications requiring high linearity and low insertion loss. Therefore, how to reduce signal loss of RF device in RF applications and improve linearity of RF device becomes an urgent problem to be solved.

More information about methods for forming RF devices may refer to U.S. patent application “US20050128026A1.”

### SUMMARY

The present disclosure provides a method for forming RF devices to reduce signal loss of RF devices in RF applications and improve linearity of RF devices.

In order to solve the problems mentioned above, a method for forming a RF device is provided. According to embodiments of the present disclosure, the method may include: providing a semiconductor-on-insulator layer, which includes a back substrate, a buried oxide layer covering the back substrate and a top semiconductor layer covering the buried oxide layer, where a plurality of transistors and an interlayer dielectric layer covering the plurality of transistors are formed on a surface of the top semiconductor layer; providing a temporary supporting layer having a smooth surface, and adhering a surface of the interlayer dielectric layer to the temporary supporting layer; removing the back substrate to expose the buried oxide; providing a high resistivity substrate, and adhering the high resistivity substrate to the buried oxide layer; and removing the temporary supporting layer to expose the surface of the interlayer dielectric layer after the high resistivity substrate and the buried oxide layer is adhered.

In some embodiments, adhering a surface of the interlayer dielectric layer to the temporary supporting layer may include: adhering the surface of the interlayer dielectric layer to the temporary supporting layer with a binder.

In some embodiments, a surface of the interlayer dielectric layer may be adhered to the temporary supporting layer with a bonding process.

In some embodiments, the high resistivity substrate may be adhered to the buried oxide layer with a bonding process.

In some embodiments, a bonding temperature of the bonding process may be from 400° C. to 600° C.

In some embodiments, the temporary supporting layer may be a silicon wafer, a glass wafer or a ceramic wafer.

In some embodiments, the high resistivity substrate may be a high resistivity silicon wafer or an insulation glass wafer.

In some embodiments, a method for removing the back substrate may be a chemical mechanical polishing process, an etching process, or a combination thereof.

In some embodiments, the method may further include forming an interconnection metal layer to cover the interlayer dielectric layer

In some embodiments, if a binder is used to adhere the surface of the interlayer dielectric layer to the temporary supporting layer, a method for removing the temporary supporting layer may include: heating the binder until the binder is decomposed or softened under a temperature ranging from 100° C. to 300° C.

Compared with the prior art, the present disclosure has the following advantages.

The back substrate is removed and replaced with a high resistivity substrate. Therefore, in RF applications of the RF devices formed in this disclosure, RF signals cannot pass through the high resistivity substrate easily, so that signal loss is low, and signal linearity is high. Moreover, because the surface of the interlayer dielectric layer is adhered to the temporary supporting layer, the plurality of transistors and the interlayer dielectric layer can be protected from damages in a subsequent moving process.

Further, a binder is used to adhere the interlayer dielectric layer to the temporary supporting layer, so that the temporary supporting layer can be easily removed, and the removed temporary supporting layer can be reused in subsequent processes to save costs.

Further, a bonding method is used to adhere the high resistivity substrate to the buried oxide layer, so that bond strength is great because intermolecular bonding force exists between the high resistivity substrate and the buried oxide layer, and stability of the RF device is high.

Further, the temporary supporting layer may be a silicon wafer, a glass wafer or a ceramic wafer. All of them have a smooth surface and a great mechanical strength, and do not pollute subsequent processes.

### BRIEF DESCRIPTION OF THE DRAWINGS

FIG. 1 schematically illustrates a cross-sectional view of a conventional Radio Frequency (RF) device formed on a Silicon-on-insulator (SOI) substrate; and

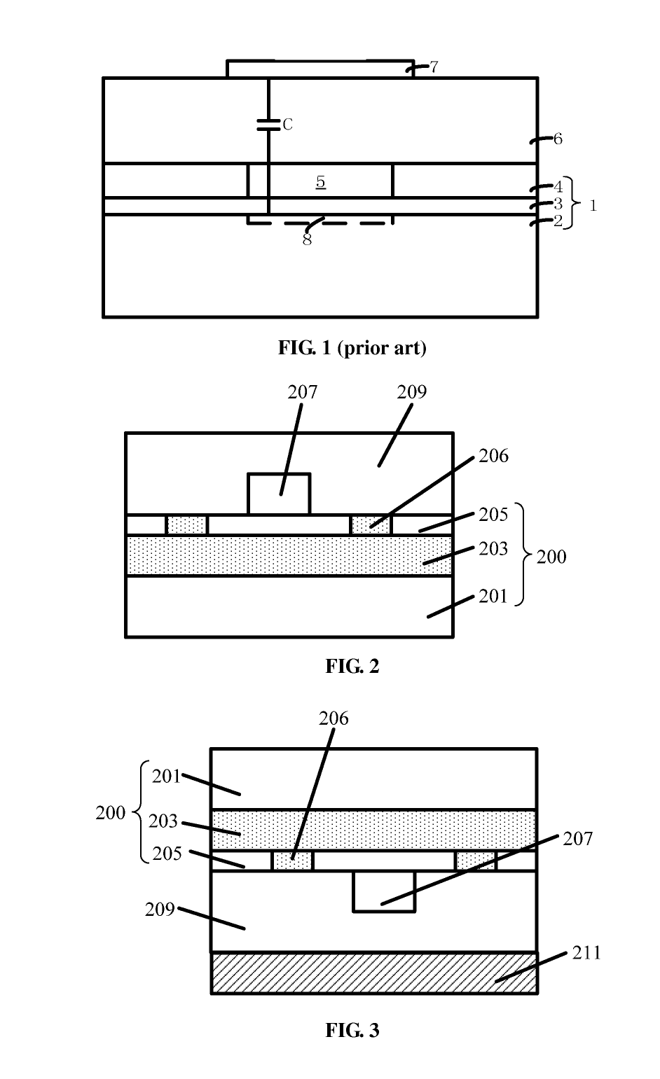

FIGS. 2-6 schematically illustrate intermediate structural diagrams of a method for forming a RF device according to one embodiment of the present disclosure.

### DETAILED DESCRIPTION

As described above, conventional RF devices have disadvantages of great signal loss and poor RF signal linearity.

It is found that, when a RF device is formed on a SOI substrate, RF signals can pass through a Buried Oxide (BOX) layer of the SOI substrate because the BOX layer is thin. In this disclosure, a method for forming a RF device is provided to reduce signal loss and improve RF signal linearity.

In order to clarify the objects, characteristics and advantages of the present disclosure, embodiments of the present disclosure will be described in detail in conjunction with the accompanying drawings.

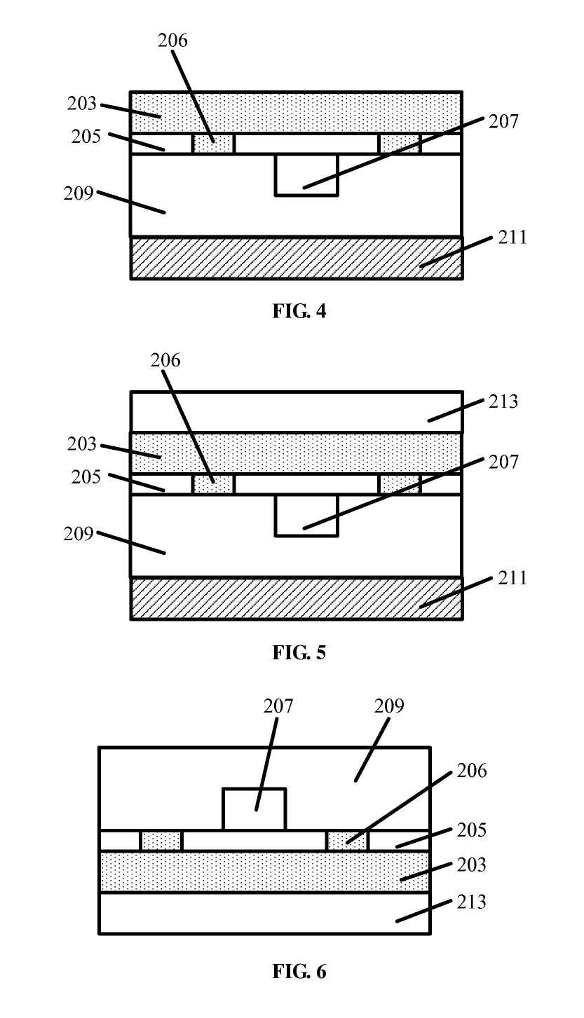

Referring to FIG. 2, a semiconductor-on-insulator layer 200 is provided, where the semiconductor-on-insulator layer 200 includes a back substrate 201, a buried oxide layer 203 covering the back substrate 201, and a top semiconductor layer 205 covering the buried oxide layer 203. A plurality of transistors 207 and an interlayer dielectric layer 209 covering the plurality of transistors 207 are formed on a surface of the top semiconductor layer 205.

The back substrate 201 may be removed and replaced with a high resistivity substrate in subsequent processes. Material of the back substrate 201 may be semiconductor, such as monocrystalline silicon, monocrystalline germanium, silicon germanium, etc. The buried oxide layer 203 is used to insulate transistors and the high resistivity substrate to prevent a signal loss. Material of the buried oxide layer 203 may be silicon oxide, germanium oxide, etc. The buried oxide layer 203 is usually thin. The top semiconductor layer 205 is used to form the plurality of transistors 207 on its surface. Material of the top semiconductor layer 205 may be monocrystalline silicon, monocrystalline germanium, silicon germanium, etc. In one embodiment of the present disclosure, the semiconductor-on-insulator layer 200 may be Silicon-on-insulator (SOI).

The plurality of transistors 207 may be used as components of RF devices, and communicate with an interconnection metal layer in subsequent processes. The plurality of transistors 207 may be MOS transistors, Fin Field-Effect Transistors (FINFETs), Gate-All-Around transistors, etc. The method for forming the plurality of transistors 207 is known to those skilled in the art, and is not described in detail herein.

It should be noted that, in embodiments of the present disclosure, a plurality of shallow trench isolation structures are formed in the top silicon layer 205 to isolate adjacent transistors 207.

The interlayer dielectric layer 209 is used to isolate adjacent transistors 207, and protect the plurality of transistors 207 from damage in subsequent processes. The interlayer dielectric layer 209 may be formed by a chemical vapor deposition method. Material of the interlayer dielectric layer 209 may be insulation materials, such as silicon oxide, silicon nitride, silicon oxynitride, etc. In one embodiment of the present disclosure, material the interlayer dielectric layer 209 may be silicon oxide.

It should be noted that, in one embodiment of the present disclosure, before adhering a surface of the interlayer dielectric layer 209 to a temporary supporting layer 211, an interconnection metal layer and a surface passivation layer are formed on the surface of the interlayer dielectric layer 209. Namely, entire integration circuit process has been completed.

Referring to FIG. 3, a temporary supporting layer 211 with a smooth surface is provided, and a surface of the interlayer dielectric layer 209 and the temporary supporting layer 211 are adhered.

Inventors of the present disclosure found that, the problems mentioned above may be solved by removing the back substrate 201 of the semiconductor-on-insulator layer 200, and replacing the back substrate 201 with a high resistivity substrate. However, in subsequent processes to move the structure with the interlayer dielectric layer 209 formed therein and replace the back substrate with a high resistivity substrate, if the structure is not protected, the interlayer dielectric layer 209 and the plurality of transistors 207 formed therein may be damaged.

The temporary supporting layer 211 is used to provide mechanical support and protection in subsequent processes. For example, when the structure is held by a mechanical hand, the temporary supporting layer 211 can protect the interlayer dielectric layer 209 and transistors formed therein from damage. The temporary supporting layer 211 has a smooth surface, which contacts the interlayer dielectric layer 209. In one embodiment of the present disclosure, in order to protect the structure from pollution of material of the temporary supporting layer 211, and provide proper mechanical support and protection in subsequent processes, the temporary supporting layer 211 may be a silicon wafer, a glass wafer or a ceramic wafer. The silicon wafer or the glass wafer has a great mechanical strength, and a smooth surface.

The surface of the interlayer dielectric layer 209 is adhered to the temporary supporting layer 211 with a binder or a bonding process using intermolecular bonding force. If the binder is used, the interlayer dielectric layer 209 and the temporary supporting layer 211 may be separated easily in subsequent processes. If the bonding method is used, the interlayer dielectric layer 209 and the temporary supporting layer 211 may be adhered more closely because of great intermolecular bonding force.

In one embodiment of the present disclosure, because the temporary supporting layer 211 may be removed in subsequence processes, in order to facilitate subsequent removal process, a binder (e.g., Brewer Science, HT-10.10) may be preferably used to adhere the surface of the interlayer dielectric layer 209 to the temporary supporting layer 211.

In one embodiment, a step for adhering a surface of the interlayer dielectric layer 209 to the temporary supporting layer 211 may include: overturning the structure which has the interlayer dielectric layer 209 and the plurality of transistors 207 formed therein, to make a surface of the back substrate 201 up and a surface of the interlayer dielectric layer 209 down; and adhering the temporary supporting layer 211 to the overturned structure with a binder.

It should be noted that, in some embodiments of the present disclosure, after adhering the temporary supporting layer 211 to the interlayer dielectric layer 209 with a binder, overturning is performed to make a surface of the back substrate 201 up, so that the back substrate 201 can be easily removed in subsequent processes.

Referring to FIG. 4, the back substrate 201 is removed (as shown in FIG. 3) to expose the buried oxide 203.

A method to remove the back substrate 201 may be a chemical mechanical polishing process, an etching process, or a combination thereof. In one embodiment of the present disclosure, a chemical mechanical polishing process is performed to remove a part of the back substrate 201 firstly, and then a wet etching process is performed to remove the remaining part of the back substrate 201. In this way, the back substrate 201 is removed completely, and a surface, which is close to the back substrate 201, of the buried oxide layer 203 is less damaged.

Referring to FIG. 5, a high resistivity substrate 213 is provided, and the high resistivity substrate 213 and the buried oxide layer 203 are adhered.

Inventors of the present disclosure found that, RF signals cannot pass through the high resistivity substrate 213 easily. Signal loss can be reduced, and signal linearity can be improved by adopting the high resistivity substrate 213. The high resistivity substrate 213 is used to replace the back substrate 201, so as to achieve purposes of reducing signal loss and improve signal linearity. The high resistivity substrate 213 may be a high resistivity silicon wafer, an insulation glass wafer or other smooth insulation material which can be easily cut, where the high resistivity silicon wafer may be formed by low concentration doping process. In one embodiment of the present disclosure, a glass wafer is used as the high resistivity substrate 213. Because the glass wafer is completely insulating, RF signals cannot pass through the glass wafer. Therefore, signal loss of RF devices formed in subsequent processes can be reduced, and signal linearity is improved.

The high resistivity substrate 213 is adhered to the buried oxide layer 203 with a binder or a bonding process using intermolecular bonding force. Because the high resistivity substrate 213 acts as a part of the RF devices formed subsequently, bond strength between the high resistivity substrate 213 and the buried oxide layer 203 may influence stability of the RF device. In one embodiment of the present disclosure, the bonding method may be preferably used to adhere the high resistivity substrate 213 to the buried oxide layer 203.

In one embodiment of the present disclosure, a bonding temperature of the boding process may be from 400° C. to 600° C. Under this process parameter, the high resistivity substrate 213 and the buried oxide layer 203 may be adhered more closely, so that the stability of the RF device is high.

Referring to FIG. 6, after the high resistivity substrate 213 and the buried oxide layer 203 are adhered, the temporary supporting layer 211 may be removed to expose a surface of the interlayer dielectric layer 209.

A step for removing the temporary supporting layer 211 may include: overturning the adhered structure of the high resistivity substrate 213 and the buried oxide layer 203 to make a surface of the temporary supporting layer 211 up; and heating the binder to a certain temperature to decompose and soften the binder, so as to remove the temporary supporting layer 211. In one embodiment of the present disclosure, because the interlayer dielectric layer is adhered to the temporary supporting layer with the binder, a method for removing the temporary supporting layer may include: heating the binder until the binder is decomposed or softened under a temperature ranging from 100° C. to 300° C.

It should be noted that, in some embodiments, the temporary supporting layer 211, which is removed, can be reused in subsequent processes, so as to save costs.

After above steps are performed, RF devices are finished according to one embodiment of the present disclosure. The back substrate is removed and replaced with a high resistivity substrate. Therefore, in RF applications of the RF devices formed in this disclosure, RF signals cannot pass through the high resistivity substrate easily, so that signal loss is low, and signal linearity is high. Moreover, because the surface of the interlayer dielectric layer is adhered to the temporary supporting layer, the plurality of transistors and the interlayer dielectric layer can be protected from damages in a subsequent moving process.

Further, a binder is used to adhere the interlayer dielectric layer to the temporary supporting layer, so that the temporary supporting layer can be easily removed, and the removed temporary supporting layer can be reused in subsequent processes to save costs.

Further, a bonding method is used to adhere the high resistivity substrate to the buried oxide layer, so that bond strength is great because intermolecular bonding force exist between the high resistivity substrate and the buried oxide layer, and stability of the RF device is high.

Further, the temporary supporting layer may be a silicon wafer, a glass wafer or a ceramic wafer. All of them have a smooth surface and a great mechanical strength, and do not pollute subsequent processes.

Although the present disclosure has been disclosed above with reference to preferred embodiments thereof, it should be understood by those skilled in the art that various changes may be made without departing from the spirit or scope of the disclosure. Accordingly, the present disclosure is not limited to the embodiments disclosed.

What is claimed is:

1. A method for forming a radio frequency device, comprising:
providing a semiconductor-on-insulator layer, which comprises a back substrate, a buried oxide layer covering the back substrate and a top semiconductor layer covering the buried oxide layer, where a plurality of transistors and an interlayer dielectric layer covering the plurality of transistors are formed on a surface of the top semiconductor layer;
providing a temporary supporting layer having a smooth surface, and adhering a surface of the interlayer dielectric layer to the temporary supporting layer;
removing the back substrate to expose the buried oxide;
providing a high resistivity substrate, and adhering the high resistivity substrate to the buried oxide layer; and
removing the temporary supporting layer to expose the surface of the interlayer dielectric layer after the high resistivity substrate and the buried oxide layer is adhered.

2. The method according to claim 1, wherein adhering a surface of the interlayer dielectric layer to the temporary supporting layer comprises: adhering the surface of the interlayer dielectric layer to the temporary supporting layer with a binder.

3. The method according to claim 1, wherein the surface of the interlayer dielectric layer is adhered to the temporary supporting layer with a bonding process.

4. The method according to claim 1, wherein the high resistivity substrate is adhered to the buried oxide layer with a bonding process.

5. The method according to claim 4, wherein a bonding temperature of the bonding process is from 400° C. to 600° C.

6. The method according to claim 1, wherein the temporary supporting layer is a silicon wafer, a glass wafer or a ceramic wafer.

7. The method according to claim 1, wherein the high resistivity substrate is a high resistivity silicon wafer or an insulation glass wafer.

8. The method according to claim 1, wherein a method for removing the back substrate is a chemical mechanical polishing process, an etching process, or a combination thereof.

9. The method according to claim 1, further comprising: forming an interconnection metal layer to cover the interlayer dielectric layer.

10. The method according to claim 1, wherein if a binder is used to adhere the surface of the interlayer dielectric layer to the temporary supporting layer, a method for removing the temporary supporting layer comprises: heating the binder until the binder is decomposed or softened under a temperature ranging from 100° C. to 300° C.
